(19) United States
(12) Patent Application Publication
(10) Pub. No.: US 2012/0085888 A1
(43) Pub. Date: Apr. 12, 2012

(54) BACK-SIDE ILLUMINATED SOLID-STATE IMAGING DEVICE

(75) Inventors: Takefumi ENDO, Kanagawa (JP); Shinji KOMORI, Kanagawa (JP); Narumi SAKASHITA, Kanagawa (JP)

(73) Assignee: RENESAS ELECTRONICS CORPORATION, Kanagawa (JP)

(21) Appl. No.: 13/239,628

(22) Filed: Sep. 22, 2011

(30) Foreign Application Priority Data
Oct. 8, 2010 (JP) 2010-228473

(51) Int. Cl. H01L 27/146; H01L 31/119

(52) U.S. Cl. 250/208.1; 257/292; 257/E31.091

(57) ABSTRACT

A back-side illuminated solid-state imaging device includes a photodiode and MOS transistors at a semiconductor substrate. The MOS transistors are formed over the front surface of the semiconductor substrate. The photodiode responds to an incident light applied to the back surface opposite to the front surface of the semiconductor substrate. A charge storing portion, and a first and second transfer gates are formed over the main part of the photodiode and the front surface of the semiconductor substrate located above the vicinity of the main part so as to achieve the global shutter function. Since the irradiation light is incident on the photodiode from the back surface of the semiconductor substrate in back-side illuminated solid-state imaging device, the sensitivity of the photodiode is not reduced even when the first and second transfer gates, and the charge storing portion are formed to achieve the global shutter function.

### CROSS-REFERENCE TO RELATED APPLICATIONS

The disclosure of Japanese Patent Application No. 2010-228473 filed on Oct. 8, 2010 including the specification, drawings and abstract is incorporated herein by reference in its entirety.

### BACKGROUND

The present invention relates to back-side illuminated solid-state imaging devices, such as a back-side illuminated CMOS image sensor, and more particularly to an effective technique that can suppress reduction in sensitivity of a photodiode (PD) when performing the function of a global shutter.

Charge-coupled device (CCD) image sensors and complementary metal-oxide-semiconductor (CMOS) image sensors are known as an image sensor serving as a solid-state imaging device.

A CCD image sensor includes a circuit for reading charges generated by irradiated light, from a photodiode (PD) as a light receiving element, and the circuit uses an element called a charge-coupled device (CCD). The CCD image sensor can sequentially output pixel information by use of the CCD. In contrast, the CMOS image sensor includes, in each pixel, a transistor for amplifying charges generated by an irradiated light from a photodiode (PD) as a light receiving element. Thus, the CMOS image sensor can amplify and read an output from an arbitrary pixel selected, which enables reading out of a random-accessed image.

As is well known, the CCD image sensor includes a plurality of photodiodes (PD) arranged in row and column directions of a matrix. First, information stored in pixels of the photodiodes (PD) arranged in the column direction is read out by vertical CCDs. Then, information stored in pixels of the vertical CCDs arranged in the column direction is read out by an image reader using horizontal CCDs arranged in the row direction. All pixel information is subsequently output from the image reader, but is stored at the same timing. By combination with an electronic shutter, the CCD image sensor enables the global shutter imaging which does not create distortion of images captured due to a difference in exposure timing even when making a picture of an object moving at a high speed. In contrast, the CMOS image sensor reads out all pixels by subsequently reading each selected row of pixel information, so that when taking a picture of an object moving at a high speed, there occurs photographing using a rolling shutter which will cause distortion of images captured.

The following Patent Document 1 discloses an X-Y address type CMOS solid-state imaging device (CMOS sensor) with a charge storing section and a transmission gate added to the unit of pixel in order for the CMOS image sensor to achieve the global shutter function that can be obtained by the CCD image sensor.

Further, the following Patent Document 2 discloses a back-side illuminated CMOS image sensor configured so as to solve the problem of reflection of a part of incident light by an interconnect layer in the related-art front-side illuminated CMOS image sensor when the incident light is applied through the interconnect layer disposed above a photodiode (PD). In this back-side illuminated CMOS image sensor, the interconnect layer is formed over the front surface of a silicon layer with the photodiode (PD) formed therein, whereby the incident light is taken in from the back surface opposite to the front surface with the interconnect layer formed thereon. This arrangement does not need any interconnection taking into consideration a light receiving surface, and thus can improve the flexibility in interconnection for a pixel.

Moreover, the following Patent Document 3, Patent Document 4, and Patent Document 5 also disclose a back-side illuminated CMOS image sensor which is similar to that disclosed in the above Patent Document 2.

### RELATED ART DOCUMENTS

### Patent Documents

### [Patent Document 1]

Japanese Unexamined Patent Publication No. 2004-111590

### [Patent Document 2]

Japanese Unexamined Patent Publication No. 2003-031785

### [Patent Document 3]

Japanese Unexamined Patent Publication No. 2005-268644

### [Patent Document 4]

U.S. Patent Application Publication 2008/0217723A1

### [Patent Document 5]

U.S. Patent Application Publication 2010/0140675A1

### SUMMARY The inventors are involved in the development of CMOS image sensors having a global shutter function prior to the present invention.

First, a CMOS image sensor having a global shutter function can be achieved by adding a charge storage portion and a transmission gate unit between each photodiode (PD) serving as a charge generator and a selected transistor for readout to a related art CMOS sensor reading circuit, as disclosed in the above Patent Document 1.

As described in the above patent document 1, however, the inventors have found through their studies that when such elements are intended to be added over the surface of a silicon layer with the photodiodes (PD) of the front-side illuminated CMOS image sensor formed therein, an area of receiving an irradiated light at the photodiode (PD) is decreased with respect to the superficial area of the silicon layer, which results in reduction in sensitivity of the photodiode (PD).

In contrast, the inventors have studied in detail the back-side illuminated CMOS image sensor disclosed in the above Patent Document 2, the above Patent Document 3, the above Patent Document 4, and the above Patent Document 5, prior to making the invention.

In the back-side illuminated CMOS image sensor disclosed in the above Patent Document 3, photodiodes (PD) and readout MOS transistors are formed at the front surface of a silicon semiconductor substrate, and a multi-layered interconnect layer is formed above the front surface of the silicon semiconductor substrate via an interlayer insulating film, such as a silicon oxide film. From the back surface of the silicon semiconductor substrate, light is applied to the photodiodes (PD) via on-chip lenses and color filters.

However, the inventors have found through their studies that in the back-side illuminated CMOS image sensor disclosed in the above Patent Document 3, no interconnect layer or gate electrode of the MOS transistor is formed between a main part of the surface of the photodiode (PD) element formed at the front surface of the silicon semiconductor substrate and the multilayer interconnect layer formed above the front surface of the element. Also in the back-side illuminated CMOS image sensor disclosed in the above Patent Document 2, no interconnect layer or gate electrode of the MOS transistor is formed between the main part of the surface of the photodiode (PD) element and the multilayer interconnect layer formed over the surface of the element. Likewise, in the back-side illuminated CMOS image sensors disclosed in the above Patent Document 4 and 5, no interconnect layer or gate electrode of a MOS transistor is formed above the main part of the surface of the photodiode (PD) element formed at the front surface of the silicon semiconductor substrate.

As described above, the reason why no interconnect layer or gate electrode of a MOS transistor is formed above the main part of the surface of the photodiode (PD) element in the related art back-side illuminated CMOS image sensor is due to the following historical background, which has been found trough the studies by the inventors.

That is, in the front-side illuminated CMOS image sensor developed before the back-side illuminated CMOS image sensor, incident light is applied to the front side of the photodiode (PD), and no interconnect layer or gate electrode of a MOS transistor is formed above the main part of the surface of the photodiode (PD) element. As a result, the back-side illuminated CMOS image sensor developed after the front-side illuminated CMOS image sensor also obtains the above result.

Now, a manufacturing method of a photodiode (PD) will be described below. The photodiode (PD) is formed by partly introducing N-type impurities into a P-type semiconductor region. This partial introduction employs a silicon gate process which uses a gate insulating film and a polycrystalline silicon layer serving as a gate electrode in a readout MOS transistor, as a mask to be used for permission and inhibition of the introduction of the impurities. If any other interconnect layer or a gate electrode of the MOS transistor is formed above the main part of the surface of the photodiode (PD) element before introducing the N-type impurities, the interconnect layer or gate electrode will function as an undesired mask. As a result, when the photodiode (PD) of the front-side illuminated or back-side illuminated CMOS image sensor is formed using an extremely normal silicon gate manufacturing process in a CMOS semiconductor integrated circuit, the existence of the interconnect layer or gate electrode of the MOS transistor formed above the main part of the surface of the photodiode (PD) element is not desired at all.

According to the above-mentioned historical background, also in the back-side illuminated CMOS image sensor developed after the front-side illuminated CMOS image sensor, no interconnect layer or gate electrode of the MOS transistor is formed above the main part of the surface of the photodiode (PD) element.

Thus, the back-side illuminated CMOS image sensor is restricted by the rule of interconnection in a silicon gate manufacturing process of the CMOS semiconductor integrated circuit for providing such a front-side illuminated CMOS image sensor. In such a back-side illuminated CMOS image sensor, the addition of elements of the charge storage portion and the transmission unit for achieving the function of the global shutter function leads to reduction in sensitivity of the photodiode (PD). This is because the addition of elements is performed in a part other than areas for formation of the photodiodes (PD) at the surface of the silicon semiconductor substrate with the photodiodes (PD) of the CMOS image sensor formed thereover, which leads to a decrease in area occupied by the photodiodes (PD) with respect to the silicon semiconductor substrate, thus reducing the sensitivity of the photodiode (PD).

The inventors, however, have found through their studies that the back-side illuminated CMOS image sensor does not need to be restricted by the rule of interconnection in the silicon gate manufacturing process of the CMOS semiconductor integrated circuit for providing the front-side illuminated CMOS image sensor.

First, since in the back-side illuminated CMOS image sensor, the irradiation light is incident on the photodiode (PD) from the back surface of the silicon semiconductor substrate, even if an interconnect layer or a gate electrode of the MOS transistor is formed above the main surface part of each photodiode (PD) formed at the front surface of the silicon semiconductor substrate, the sensitivity of the photodiodes (PD) is not reduced.

In a manufacturing method of the photodiodes (PD), after partial introduction of N-type impurities into a P-type semiconductor region using a gate insulating film and a polycrystal silicon layer of the gate electrode of the MOS transistor as a mask, an interconnect layer or a gate electrode of the MOS transistor can be formed above the main part of the surface of the photodiodes (PD) formed at the surface of the silicon semiconductor substrate via a passivation film made of a silicon dioxide layer or the like.

The present invention has been made as a result of studies performed by the inventors prior to the invention as described above.

Accordingly, it is an object of the present invention to provide a back-side illuminated solid-state imaging device which has the global shutter function and which can suppress the reduction in sensitivity of the photodiode (PD).

The above and other objects and the novel features of the invention will become apparent from the description of the present specification and the accompanying drawings.

Representative aspects of the invention disclosed in the present application will be briefly described below.

That is, according to the typical embodiment of the invention, the back-side illuminated solid-state imaging device is provided which includes photodiodes (3) and MOS transistors (Q1, Q2, and Q3) at the semiconductor substrate (1). The above-mentioned MOS transistor is formed over the front surface of the semiconductor substrate. The photodiode responses to the incident light applied to the back surface opposite to the front surface of the semiconductor substrate.

Further, a charge storage portion (TH) for achieving the global shutter function is provided over the front surface of the semiconductor substrate located above the main part of the photodiode.

The effects obtained by the typical aspects of the invention disclosed in the present application will be briefly described as follows.

That is, according to the invention, the back-side illuminated solid-state imaging device can be provided which has the global shutter function of being capable of suppressing the reduction in sensitivity of the photodiode (PD).

### BRIEF DESCRIPTION OF THE DRAWINGS

FIG. 1 is a diagram showing the structure of a back-side illuminated CMOS image sensor according to a first embodiment of the invention;

FIG. 2 is a diagram showing an equivalent circuit of the back-side illuminated CMOS image sensor having the structure shown in FIG. 1 in the first embodiment of the invention;

FIG. 3 is a diagram showing the structure of a back-side illuminated CMOS image sensor according to a second embodiment of the invention;

FIG. 4 is a diagram showing an energy band structure of a main part of the element of the back-side illuminated CMOS image sensor in a reset operation in the second embodiment of the invention shown in FIG. 3;

FIG. 5 is a diagram showing an energy band structure of a main part of the element when signal electrons are stored in an N⁻impurity region 2 of the photodiode (PD) while incident light LG is applied to the back-side illuminated CMOS image sensor by back irradiation in the second embodiment of the invention shown in FIG. 3;

FIG. 6 is a diagram showing an energy band structure of a main part of the element when the signal electrons SC are transferred to a charge storage portion TH in the back-side illuminated CMOS image sensor in the second embodiment of the invention shown in FIG. 3;

FIG. 7 is a diagram showing the structure of a back-side illuminated CMOS image sensor according to a third embodiment of the invention;

FIG. 8 is a diagram showing another structure of a back-side illuminated CMOS image sensor according to the third embodiment of the invention;

FIG. 9 is a diagram showing a circuit configuration of a back-side illuminated CMOS image sensor in which a readout MOS transistor Q1, a vertical selection MOS transistor Q2, and a reset control MOS transistor Q3 are shared among pixel structures according to a fourth embodiment of the invention;

FIG. 10 is a diagram showing a layout structure of a semiconductor chip of a semiconductor integrated circuit 1 in which the readout MOS transistor Q1, the vertical selection MOS transistor Q2, and the reset control MOS transistor Q3 are shared between pixel structures PIXEL1 and PIXEL2 in the back-side illuminated CMOS image sensor according to the fourth embodiment of the invention shown in FIG. 9;

FIG. 11 is a diagram showing the structure of the back-side illuminated CMOS image sensor according to the most specific fifth embodiment of the invention; and

FIG. 12 is a diagram showing signal waveforms relating to the operation of the back-side illuminated CMOS image sensor in the fifth embodiment of the invention shown in FIG. 11.

### DETAILED DESCRIPTION

### 1. Outline of Embodiments

First, the outline of typical embodiments of the invention disclosed in the present application will be described below. Reference characters within parentheses in the accompanying drawings, with reference to which the outline of the typical embodiments will be explained, are illustrative only, including the concepts of components to which the respective reference characters are added.

[1] In the typical embodiment of the invention, a back-side illuminated solid-state imaging device includes a photodiode (3) and MOS transistors (Q1, Q2, Q3) over the semiconductor substrate (1). The MOS transistor is formed over the front surface of the semiconductor substrate. The photodiode responses to the light incident on the back surface opposite to the front surface of the semiconductor substrate.

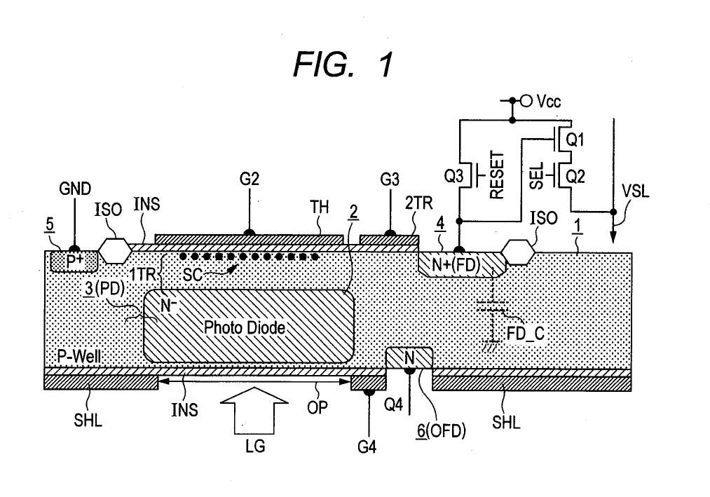

A charge storage portion (TH) for achieving the function of the global shutter is further provided over the front surface of the semiconductor substrate located above the main part of the photodiode (see. FIG. 1).

This embodiment can provide the back-side illuminated solid-state imaging device having the global shutter function that can suppress the reduction in sensitivity of the photodiode (PD).

In the preferred embodiment, the photodiode is comprised of a P-type impurity region (P-Well), and an N-type impurity region (2) formed at the semiconductor substrate. The main part of the photodiode is comprised of the N-type impurity region (see FIG. 1).

In another preferred embodiment, the back-side illuminated solid-state imaging device further includes an N-type impurity semiconductor region (4) for readout for forming a PN junction with the P-type impurity region formed in the semiconductor substrate.

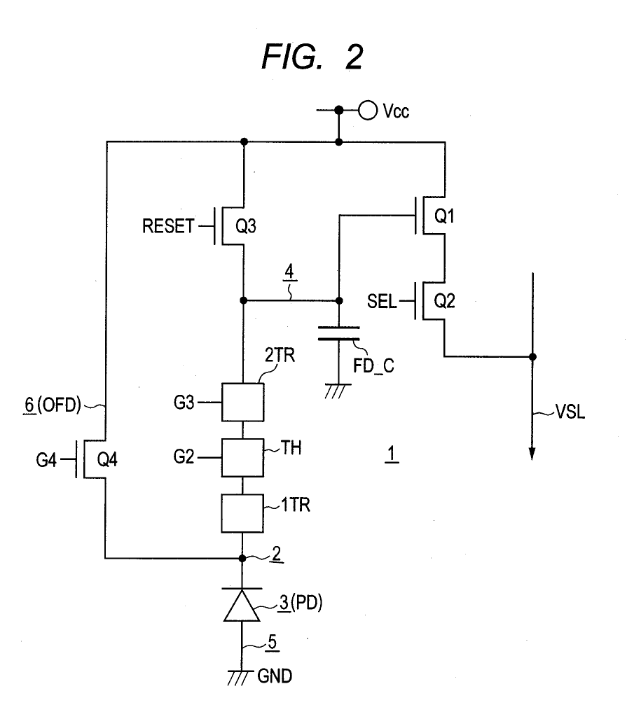

Stored charges read from the charge storing portion are converted into a signal voltage by a capacitance of the PN junction in the N-type impurity semiconductor region for readout. The signal voltage is supplied to a gate terminal of the readout MOS transistor (Q1) among the MOS transistors (see FIGS. 1 and 2).

In a further preferred embodiment, the N-type impurity region of the photodiode has the function of storing therein signal electrons in response to the incident light.

The back-side illuminated solid-state imaging device further includes, at the semiconductor substrate, a first transfer gate (1TR) coupled between the N-type impurity region (2) of the photodiode and the charge storing portion (TH), and a second transfer gate (2TR) coupled between the charge storing portion (TH) and the N-type impurity semiconductor region (4) for readout.

The first transfer gate has the function of transferring the signal electrons stored in the N-type impurity region of the photodiode to the electron charging portion. The second transfer gate has the function of transferring the signal electrons stored in the charge storing portion to the N-type impurity semiconductor region for readout (see FIG. 1).

In a more preferred embodiment, each of the charge storing portion (TH) and the second transfer gate (G3) has the structure of a surface-type MOS capacitor including the P-type impurity region, a surface insulating film formed over the front surface of the semiconductor substrate, and a gate electrode (see FIG. 2).

In another more preferred embodiment, the first transfer gate (1TR) is formed of another PN junction (PD) between the P-type impurity region located directly under the gate electrode (G2) of the charge storing portion (TH) and the N-type impurity region (2) (see FIG. 1).

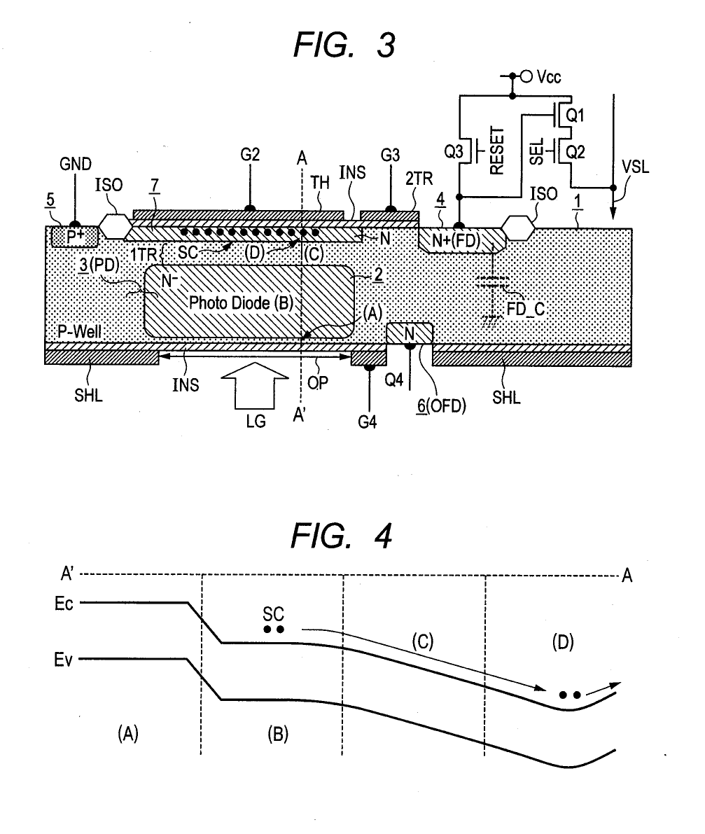

In a further more preferred embodiment, an N-type impurity semiconductor region for storing (7) that stores therein the signal electrons is formed over the front surface of the semiconductor substrate directly under the gate electrode (G2) of the charge storing portion (TH) (see FIG. 3).

In a further more preferred embodiment, the N-type impurity semiconductor region (4) for readout is set to a predetermined operation voltage (Vcc) by the reset control MOS transistor (Q3) among the MOS transistors (see FIG. 1).

In a further more preferred embodiment, a drain-source current route of the vertical selection MOS transistor (Q2) having gate terminal to which a selection control signal (SEL) is supplied among the MOS transistors is coupled in series to a drain-source current route of the readout MOS transistor (Q1). The serial coupling between the readout MOS transistor and the vertical selection MOS transistor is established between the predetermined operation potential and a vertical signal line (see FIGS. 1 and 2).

In a still further more preferred embodiment, a part of the N-type impurity region (2) is formed to extend inside the semiconductor substrate (1) directly under the N-type impurity semiconductor region (4) for readout.

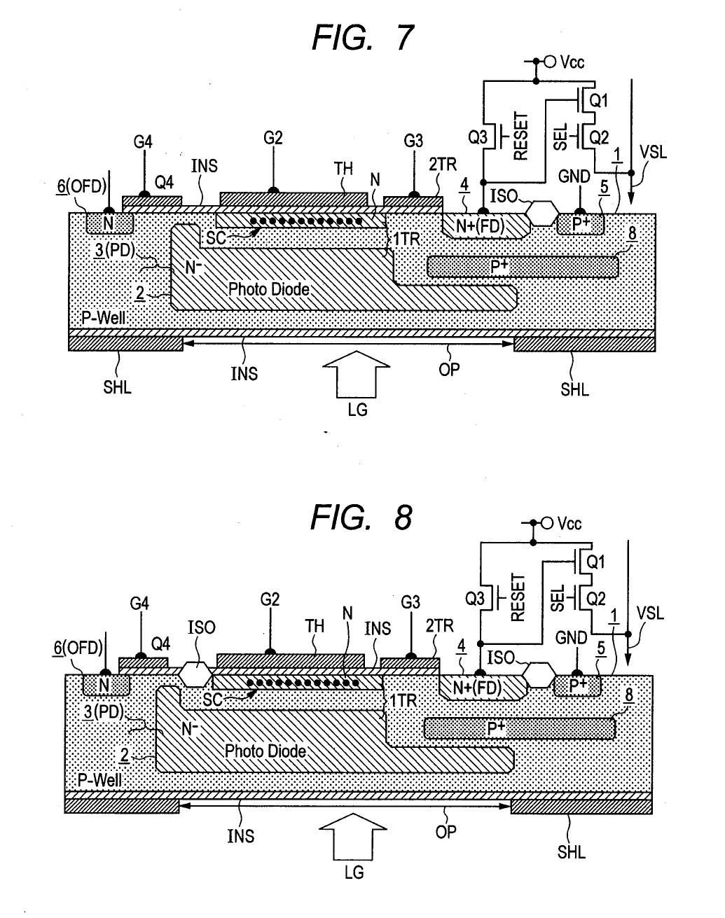

A P-type semiconductor region (8) having a high concentration of impurities is formed between the part of the N-type impurity region (2) formed to extend inside the semiconductor substrate (1) and the N-type impurity semiconductor region (4) for readout (see FIGS. 7 and 8).

In a specific embodiment, a light shielding film (SHL) is formed over the back surface of the semiconductor substrate, and has an opening (OP) for introducing into the N-type impurity region (2) of the photodiode, the incident light (LG) to be incident on the back surface of the semiconductor substrate (see FIGS. 1, 3, 7, and 8).

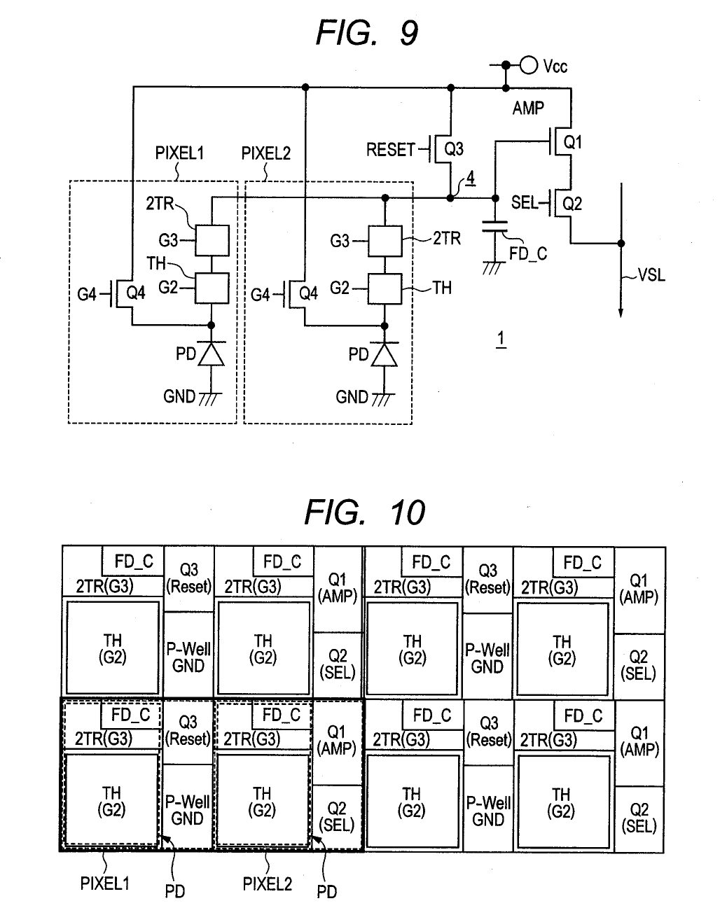

In another specific embodiment, the pixel structures (PIXEL1 and PIXEL2), each including the photodiode, the first transfer gate, the charge storing portion, and the second transfer gate, are formed over the semiconductor substrate. The readout MOS transistor (Q1), the vertical selection MOS transistor (Q2), and the reset control MOS transistor (Q3) are shared between the pixel structures (see FIGS. 9 and 10).

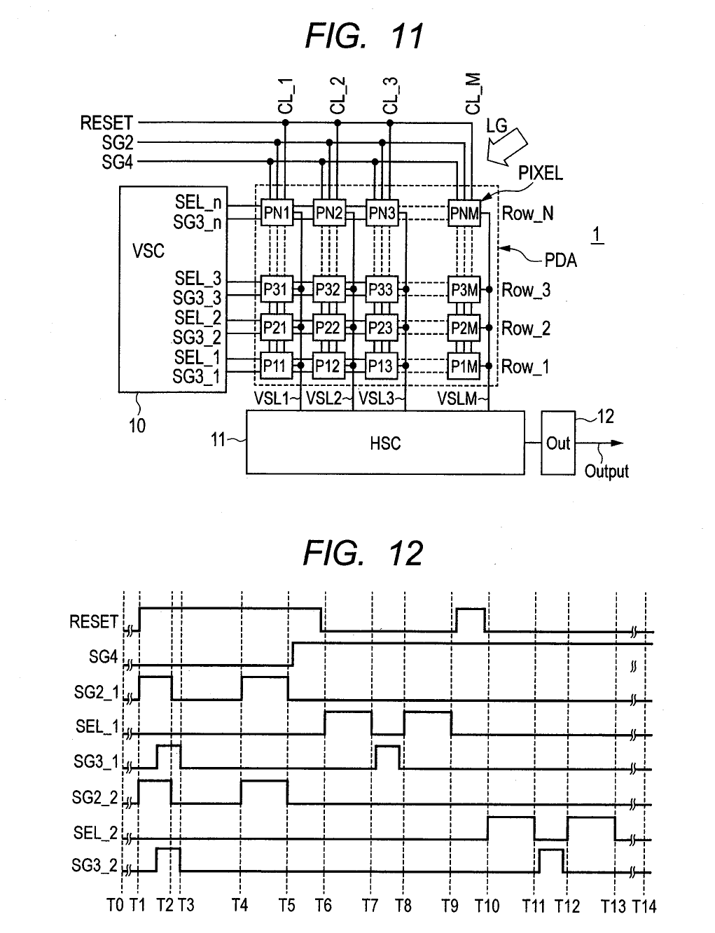

In a furthermore specific embodiment, pixel structures are located at points of intersection between a plurality of rows (Row_1, Row _2 , and Row_3 to Row_N) and a plurality of columns (CL_1, CL_2, and CL_3 to CL_M) in an array (PDA). Each of the pixel structures includes the photodiode, the first transfer gate, the charge storing portion, the second transfer gate, the readout MOS transistor (Q1), the vertical selection MOS transistor (Q2), and the reset control MOS transistor (Q3). The array (PDA) is coupled to a vertical scanning circuit (10) of the CMOS circuit and a horizontal scanning circuit (11) of the CMOS circuit (see FIG. 11).

In the most specific embodiment, the output from the horizontal scanning circuit (11) is coupled to the input of an output circuit (12) of the CMOS circuit (see FIG. 11).

### 2. Details of Embodiments

Next, the embodiments will be further described below in more detail. In all drawings for explaining the best mode for carrying out the invention, parts having the same functions as those shown in the above-mentioned drawings are designated by the same reference characters, and its repeated description will be omitted below.

### First Embodiment 1

### <<Structure of Back-Side Illuminated CMOS Image Sensor>>

FIG. 1 shows the structure of a back-side illuminated CMOS image sensor according to a first embodiment of the invention.

As shown in FIG. 1, the readout MOS transistor Q1, the vertical selection MOS transistor Q2, and the reset control MOS transistor Q3 are formed over the upper surface of the P-type well region P-Well as a silicon semiconductor substrate 1 using a silicon gate CMOS semiconductor manufacturing process. In FIG. 1, the MOS transistors Q1, Q2, and Q3 are drawn in such a manner as to float up above the P-type well region P-Well of the silicon semiconductor substrate 1. Actually, however, the MOS transistors Q1, Q2, and Q3 are formed over the upper surface of the P-type well region P-Well of the silicon semiconductor substrate 1 by partial introduction of N-type impurities using the gate insulating film and the polycrystal silicon layer of the gate electrode of the MOS transistors as a mask.

An N⁻impurity region 2 for forming the photodiode (PD) 3 as a light receiving element is formed at the back surface from the inside of the P-type well region P-Well of the silicon semiconductor substrate 1. A light shielding film SHL formed of a conductive layer, such as metal or a polycrystal silicon layer, is formed over the back surface of the silicon semiconductor substrate 1 via an insulating film INS. An opening OP for allowing the incident light LG to be directed to the photodiode (PD) 3 as the light receiving element by the back irradiation is formed over the light shielding film SHL formed over the back surface of the silicon semiconductor substrate 1. The P-type impurity region of the P-type well region P-Well is formed between the back surface insulating film INS at the opening OP of the light shielding film SHL and the N⁻impurity region 2 of the photodiode (PD) 3, whereby an embedded photodiode (PD) is formed, thus enabling reduction in noise at a silicon interface state between the back surface insulating film INS and the back surface silicon of the silicon semiconductor substrate 1. This embedded photodiode (PD) has the similar structure to that of the photodiode with a p-type high-concentration layer as described in the above Patent Document 1, the embedded photodiode with a P+layer formed thereat as described in the above Patent Document 2, the photodiode having a P+ accumulation layer and serving as a hole accumulation diode (HAD) sensor as described in the above Patent Document 3, a pinned photodiode as described in the above Patent Document 4, or a P+ passivation or pinning layer or the like as described in the above Patent Document 5.

Further, an overflow control MOS transistor Q4 is formed over the back surface of the silicon semiconductor substrate 1. That is, the MOS transistor Q4 includes an N⁻impurity region 2 as a source region, a conductive layer G4 as a gate electrode, and an N-type overflow drain (OFD) 6 as a drain region. The overflow control MOS transistor Q4 has the function of discharging excessive electrons stored in the N⁻impurity region 2 serving as a cathode of the photodiode (PD) 3 to a power supply voltage Vcc at a high potential. A P⁺impurity region 5 is formed over the silicon semiconductor substrate 1 to couple the P-type well region P-Well of the silicon semiconductor substrate 1 serving as an anode of the photodiode (PD) 3 to a ground potential GND at a low potential. Thus, excessive holes stored in the P-type well region P-Well serving as the anode of the photodiode (PD) 3 can be discharged to the ground potential GND at the low potential. Another light shielding film, which is not shown in the back-side illuminated CMOS image sensor of the first embodiment of the invention in FIG. 1, is formed under the N-type overflow drain (OFD) 6 such that the incident light LG is not applied by the back surface irradiation to the N-type overflow drain (OFD) 6.

### <<Element Structure for Global Shutter>>

Further, in the first embodiment of the invention shown in FIG. 1, in order to achieve the function of global shutter, especially, the first transfer gate 1TR, the charge storing portion TH, and the second transfer gate 2TR are formed above the main part of the photodiode (PD) 3 comprised of the P-type well region P-Well, and N⁻impurity region 2 of the silicon semiconductor substrate 1 as the light receiving element.

The first transfer gate 1TR is formed by the PN junction between the P-type well region P-Well, and the N⁻impurity region 2 of the silicon semiconductor substrate 1. The charge storing portion TH is formed by a first surface-type MOS capacitor comprised of the gate electrode G2, the insulating film INS over the front surface of the silicon semiconductor substrate 1, and the P-type well region P-Well of the silicon semiconductor substrate 1. The second transfer gate 2TR is formed by a second surface-type MOS capacitor comprised of the gate electrode G3, the insulating film INS over the front surface of the silicon semiconductor substrate 1, the P-type well region P-Well of the silicon semiconductor substrate 1, and the N⁺impurity region 4 called “floating diffusion (FD)”.

The N⁺impurity region 4 called “floating diffusion (FD)” is formed over the upper surface of the P-type well region P-Well of the silicon semiconductor substrate 1 by partial introduction of N-type impurities using the gate insulating film of the second transfer gate 2TR and the polycrystal silicon layer of the gate electrode G3 as a mask. The N⁻impurity region 2 of the photodiode (PD) 3 is further formed deeply in the silicon semiconductor substrate 1 by high-energy ion implantation of N-type impurity ions from above the silicon semiconductor substrate 1 before formation of the polycrystal silicon layer as the gate electrode G2 of the charge storing portion TH.

<<Equivalent Circuit of Back-Side illuminated CMOS Image Sensor>>

FIG. 2 shows an equivalent circuit of the back-side illuminated CMOS image sensor having the same structure shown in FIG. 1 according to the first embodiment of the invention.

Referring to FIG. 2, the P⁺impurity region 5 of the photodiode (PD) 3 is coupled to the ground potential GND at the low potential. As shown in FIG. 2, the N⁻impurity region 2 of the photodiode (PD) 3 is coupled to the N⁺impurity region 4 of the floating diffusion (FD) via the first transfer gate 1TR, the charge storing portion TH, and the second transfer gate 2TR, and further coupled to a source terminal of the overflow control MOS transistor Q4. An N-type overflow drain (OFD) 6 of the overflow control MOS transistor Q4 is coupled to the high-potential power supply voltage Vcc.

The N⁺impurity region 4 of the floating diffusion (FD) is coupled to one end of the capacitance FD_C of the PN junction, the gate terminal of the readout MOS transistor Q1, and the source terminal of the reset control MOS transistor Q3. A drain terminal of the readout MOS transistor Q1 and a drain terminal of the reset control MOS transistor Q3 are coupled to the high-potential power supply voltage Vcc. The other end of the PN junction capacitance FD_C is coupled to the ground potential GND at the low potential. A source terminal of the readout MOS transistor Q1 is coupled to the vertical signal line VSL via a drain-source current route of the vertical selection MOS transistor Q2 which is controlled to be in a conduction state by a selection control signal SEL supplied to the gate terminal.

<<Imaging Operation of Back-Side illuminated CMOS Image Sensor>>

The back-side illuminated CMOS image sensor according to the first embodiment of the invention shown in FIGS. 1 and 2 performs the following imaging operation.

When the incident light LG is applied to the photodiode (PD) 3 serving as a light receiving element by the back surface irradiation, electrons are excited from a valence band of the silicon to a conduction band thereof due to photon of the incident light LG in a depletion layer of the PN junction of the photodiode (PD) 3 to thereby generate electron-hole pairs in the depletion layer of the PN junction. Thus, electrons and holes of the electron-hole pairs generated in the depletion layer of the PN junction respectively flow into the N⁻impurity region 2 of the PN junction and the P-type well region P-Well of the silicon semiconductor substrate 1 along a potential gradient of the depletion layer of the PN junction, so that a signal current flows into the PN junction in response to the incident light LG. As a result, the photodiode (PD) 3, which is formed by the PN junction between the P-type dwell region P-Well and the N⁻impurity region 2 of the silicon semiconductor substrate 1, converts the incident light LG given by the back surface irradiation into signal charges substantially in proportion to the amount of the light, so that the signal electrons are stored in the N⁻impurity region 2.

In response to the high-potential control voltage supplied to the gate electrode G2 of the charge storing portion TH, the potential barrier of the PN junction of the first transfer gate 1TR formed by the PN junction between the P-type well region P-Well and the N⁻impurity region 2 of the silicon semiconductor substrate 1 is lowered. Thus, the signal electrons stored in the N⁻impurity region 2 are implanted into the region P-Well region of the silicon semiconductor substrate 1. A potential well (well at a potential) having a high potential is formed at the surface of the P-type well P-Well directly under the gate electrode G2 by the MOS electric field effect exhibited due to the high-potential control voltage supplied to the gate electrode G2 of the charge storing portion TH. Thus, the signal electrons SC implanted are stored in the potential well at the surface of the P-type well region P-Well directly under the gate electrode G2.

A potential well having a high potential is formed over the surface of the P-type well region P-Well directly under the gate electrode G3 by the MOS electric field effect due to the high-potential control voltage supplied to the gate electrode G3 of the second transfer gate 2TR. As a result, signal electrons SC stored in the potential well at the surface of the region P-Well directly under the gate electrode G2 of the charge storing portion TH are transferred to the potential well at the high potential in the region P-Well directly under the gate electrode G3 of the second transfer gate 2TR.

Since the N⁺impurity region 4 called “floating diffusion (FD)” is pre-charged to the level of the high-potential power supply voltage Vcc by the conduction of the reset control MOS transistor Q3, the signal electrons SC transferred to the potential well directly under the gate electrode G3 of the second transfer gate 2TR are transferred to the N⁺impurity region 4 called “floating diffusion (FD)”. As a result, the current of the signal electrons SC are converted into a signal voltage by the capacitance FC_C of the PN junction between the N⁺impurity region 4 and the P-type well region P-Well of the floating diffusion (FD). The signal voltage of the capacitance FD_C of the PN junction can be read out by the vertical signal line VSL via the readout MOS transistor Q1 operated as a source follower, and the vertical selection MOS transistor Q2 controlled by the selection control signal SEL in a conduction state.

The surface insulating layer ISO is formed over the P-type well region P-Well of the silicon semiconductor substrate 1 by a local oxidation technique. The layer ISO acts as a channel stopper for preventing the formation of an N-type surface inversion channel on the surface of a P-type silicon semiconductor.

### Effects of First Embodiment

The above-mentioned back-side illuminated CMOS image sensor shown in FIG. 1 according to the first embodiment of the invention can achieve the initial object based on the following reasons.

That is, in order to achieve the global shutter function in the back-side illuminated CMOS image sensor shown in FIG. 1, especially, the first transfer gate 1TR, the charge storing portion TH, and the second transfer gate 2TR are formed above the main part of the photodiode (PD) 3 formed of the P-type well region P-Well and the N⁻impurity region 2 of the silicon semiconductor substrate 1 as the light receiving element.

On the other hand, the incident light LG given by the back surface irradiation from the back surface of the silicon semiconductor substrate 1 can be applied to the PN junction of the photodiode (PD) 3 formed in the silicon semiconductor substrate 1 via the opening OP formed in the light shielding film SHL at the back surface of the substrate 1.

Thus, the first embodiment of the invention shown in FIG. 1 uses the above back-side illuminated CMOS image sensor to prevent the reduction in sensitivity of the photodiode (PD) 3 even when the first and second transfer gates 1TR and 2TR and the charge storing portion TH are formed above the main part of the photodiode (PD) 3 comprised of the P-Well and the N⁻impurity region 2 of the substrate 1 for achieving the global shutter function. As a result, the first embodiment of the invention can provide the back-side illuminated CMOS image sensor having the global shutter function that can suppress the reduction in sensitivity of the photodiode (PD).

### Second Embodiment

FIG. 3 shows the structure of a back-side illuminated CMOS image sensor according to a second embodiment of the invention.

The back-side illuminated CMOS image sensor according to the second embodiment of the invention shown in FIG. 3 differs from the back-side illuminated CMOS image sensor of the first embodiment of the invention shown in FIG. 1 in the following points.

That is, in the back-side illuminated CMOS image sensor according to the second embodiment of the invention shown in FIG. 3, the N-type impurity region 7 is additionally formed over the surface of the P-type well region P-Well of the silicon semiconductor substrate 1 directly under the gate electrode G2 of the charge storing portion TH.

Thus, in the second embodiment of the invention shown in FIG. 3, the charge storing portion TH is formed by the first surface-type MOS capacitor comprised of the gate electrode G2, the insulating film INS over the front surface of the silicon semiconductor substrate 1, and the N-type impurity region 7 formed over the P-Well of the substrate 1. As a result, according to the second embodiment of the invention shown in FIG. 3, the signal electrons stored in the N⁻impurity region 2 are then stored in the N-type impurity region 7 of the first surface-type MOS capacitor via the PN injunction of the first transfer gate 1TR in response o the high-potential control voltage supplied to the gate electrode G2 of the charge storing portion TH.

Thereafter, the control voltage supplied to the gate electrode G2 of the charge storing portion TH may be changed to a lower potential. In this case, the signal electrons stored in the N-type impurity region 7 are prevented from being diffused into the P-type well region P-Well of the silicon semiconductor substrate 1 by the potential barrier of the PN junction between the N-type impurity region 7 of the first capacitor and the P-type well region P-Well of the substrate 1. As a result, the back-side illuminated CMOS image sensor of the second embodiment of the invention shown in FIG. 3 can improve the storing capability of the signal electrons SC of the charge storing portion TH as compared to the back-side illuminated CMOS image sensor of the first embodiment shown in FIG. 1.

FIG. 4 shows a diagram of an energy band structure of the main part of the element of the back-side illuminated CMOS image sensor in the reset operation according to the second embodiment of the invention shown in FIG. 3. In FIG. 4, Ec indicates an energy of the conduction band of silicon, and Ev indicates an energy of the valence band of silicon.

The regions (A), (B), (C), and (D) shown in FIG. 4 correspond to the region (A) taken along the sectional line A-A′, the regions (B), (C), and (D) in the sectional structures of the back-side illuminated CMOS image sensor shown in FIG. 3, respectively. That is, the region (A) is a P-type impurity region for forming the embedded photodiode (PD) to reduce noise due to the silicon interface level, the region (B) is an N⁻impurity region 2, the region (C) is the P-type well region P-Well of the silicon semiconductor substrate 1, and the region (D) is the N-type impurity region 7.

In the reset operation, a high-potential control voltage is supplied to the gate electrode G2 of the charge storing portion TH and the gate electrode G3 of the second transfer gate 2TR, and a reset control signal RESET having a high potential is supplied to the gate terminal of the reset control MOS transistor Q3. Thus, all the reset control MOS transistor Q3, the second transfer gate 2TR, and the charge storing portion TH are brought into the conduction state, and thus the potential barrier of the P-type well region P-Well of the region (C) is lowered, so that the remaining electrons stored in the N⁻impurity region 2 of the region (B) can be reset to the high-potential power source voltage Vcc.

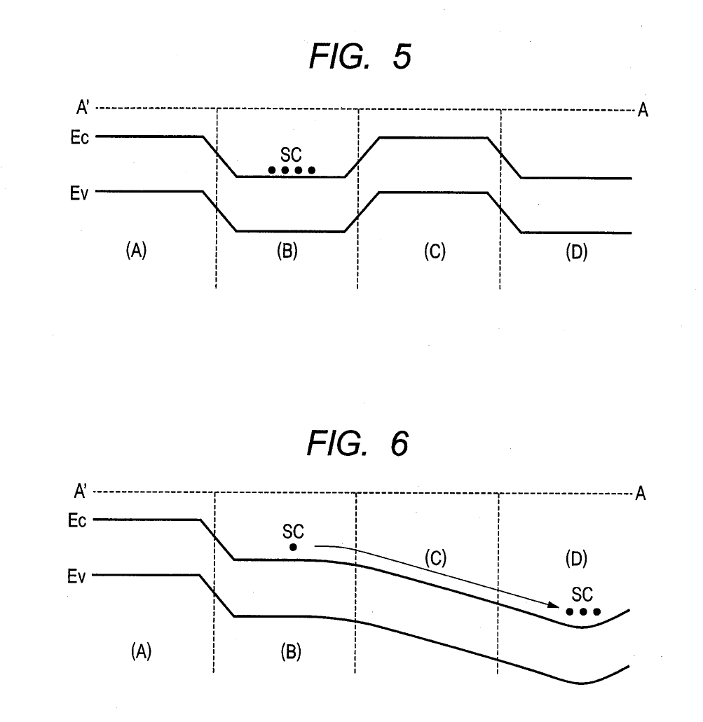

FIG. 5 shows an energy band structure of the main part of the element of the back-side illuminated CMOS image sensor when signal electrons are stored in the N⁻impurity region 2 of the photodiode (PD) while the incident light LG is applied by the back surface irradiation according to the second embodiment of the invention shown in FIG. 3.

During the charging operation, the control voltage having the low potential is supplied to the gate electrode G2 of the charge storing portion TH and the gate electrode G3 of the second transfer gate 2TR, and the reset control signal RESET having a low potential is also supplied to a gate terminal of the reset control MOS transistor Q3. Thus, all the reset control MOS transistor Q3, the second transfer gate 2TR, and the charge storing portion TH are brought into non-conduction state, so that the signal electrons SC are stored in the N⁻impurity region 2 of the region (B).

FIG. 6 shows an energy band structure of the main part of the element of the back-side illuminated CMOS image sensor when the signal electrons SC are transferred to the charge storing portion TH according to the second embodiment of the invention shown in FIG. 3.

During the transfer operation, the control voltage at a high potential is supplied to the gate electrode G2 of the charge storing portion TH. The control voltage at a low potential is supplied to the gate electrode G3 of the second transfer gate 2TR. The reset control signal RESET at a low potential is supplied to the gate terminal of the reset control MOS transistor Q3. Thus, since the potential barrier of the P-type well region P-Well in the region (C) is lowered, the remaining electrons stored in the N⁻impurity region 2 in the region (B) are transferred to the N-type impurity region 7 in the region (D).

### Third Embodiment

FIG. 7 shows the structure of a back-side illuminated CMOS image sensor according to a third embodiment of the invention.

The back-side illuminated CMOS image sensor according to the third embodiment of the invention shown in FIG. 7 differs from the back-side illuminated CMOS image sensor of the first embodiment of the invention shown in FIG. 1 in the following points.

That is, the overflow control MOS transistor Q4 formed over the back surface of the silicon semiconductor substrate 1 in the back-side illuminated CMOS image sensor of the first embodiment of the invention as shown in FIG. 1 is formed over the front surface of the substrate 1 in the back-side illuminated CMOS image sensor of the third embodiment shown in FIG. 7. As a result, in the back-side illuminated CMOS image sensor shown in FIG. 7, the gate electrode G4 of the overflow control MOS transistor Q4 and the N⁺impurity region 6 of the N-type overflow drain (OFD) are formed over the front side of the silicon semiconductor substrate 1.

Thus, in the back-side illuminated CMOS image sensor of the third embodiment of the invention shown in FIG. 7, the formation process of all the MOS transistors Q1, Q2, Q3, and Q4, the gate electrode G2 of the charge storing portion TH, and the gate electrode G3 of the second transfer gate 2TR had better be performed only over the front surface of the silicon semiconductor substrate 1. This arrangement eliminates the necessity of formation on the back surface of the substrate 1, and thus can reduce the manufacturing cost of the semiconductor.

Further, in the back-side illuminated CMOS image sensor of the third embodiment of the invention shown in FIG. 7, the N⁻impurity region 2 for forming the photodiode (PD) 3 as the light receiving element is formed up to directly under the second transfer gate 2TR and the N⁺impurity region 4 of the floating diffusion (FD). In comparison with the first embodiment and the second embodiment of the invention, the back-side illuminated CMOS image sensor of the third embodiment shown in FIG. 7 increases the area of the photodiode (PD) 3 with respect to the incident light LG and the opening OP formed in the light shielding film SHL at the back surface of the substrate 1. Thus, the back-side illuminated CMOS image sensor can improve the sensitivity of the photodiode (PD) 3 with respect to the incident light LG.

In the back-side illuminated CMOS image sensor of the third embodiment of the invention shown in FIG. 7, a P⁺impurity region 8 is added based on the reason. That is, although excessive signal electrons are caused by an increase in area of the N⁻impurity region 2 forming the photodiode (PD) 3 in response to the incident light LG, the P⁺impurity region 8 prevents the signal electrons from undesirably reaching the second transfer gate 2TR and the N⁺impurity region 4 of the floating diffusion (FD). The P⁺impurity region 8 is formed between the N⁻impurity region 2 forming the photodiode (PD) 3, and the second transfer gate 2TR and the N⁺impurity region 4 of the floating diffusion (FD), so that the excessive signal electrons can be recombined with holes in the P⁺impurity region 8.

FIG. 8 shows another structure of the back-side illuminated CMOS image sensor according to the third embodiment of the invention.

The back-side illuminated CMOS image sensor with another structure shown in FIG. 8 differs from the back-side illuminated CMOS image sensor shown in FIG. 7 in the following points.

That is, the surface insulating layer ISO is formed over the surface of the P-type silicon semiconductor between the second transfer gate 2TR and the overflow control MOS transistor Q4 by a local oxidation technique in the back-side illuminated CMOS image sensor with another structure shown in FIG. 8. The layer ISO acts as a channel stopper for preventing the formation of an N-type surface inversion channel.

Thus, the back-side illuminated CMOS image sensor with another structure shown in FIG. 8 can prevent the signal electrons stored directly under the gate electrode G2 of the second transfer gate 2TR from leaking into the high-potential power supply voltage Vcc via the overflow control MOS transistor Q4.

### Fourth Embodiment

### <<Circuit Configuration of Transistors Shared Between Pixel Structures>>

FIG. 9 shows a circuit configuration of a back-side illuminated CMOS image sensor in which a readout MOS transistor Q1, a vertical selection MOS transistor Q2, and a reset control MOS transistor Q3 are shared between pixel structures according to a fourth embodiment of the invention.

That is, in the back-side illuminated CMOS image sensor of the fourth embodiment of the invention shown in FIG. 9, the readout MOS transistor Q1, the vertical selection MOS transistor Q2, and the reset control MOS transistor Q3 are shared between the pixel structures PIXEL1 and PIXEL2. Each pixel structure of the pixel structures PIXEL1 and PIXEL2 includes the photodiode (PD), the charge storing portion TH, the second transfer gate 2TR, and the overflow control MOS transistor Q4 described in the first embodiment, the second embodiment, or the third embodiment as described above. In FIG. 9 showing each pixel structure of the pixel structures PIXL1 and PIXL2, the first transfer gate 1TR described above in the first, second, or third embodiment of the invention is not shown, but the above-mentioned first transfer gate 1TR is formed directly under the charge storing portion TH of each pixel structure. This corresponds to the formation of the first transfer gate 1TR directly under the charge storing portion TH in the above first, second, or third embodiment of the invention.

Thus, in the back-side illuminated CMOS image sensor of the fourth embodiment of the invention shown in FIG. 9, the readout MOS transistor Q1, the vertical selection MOS transistor Q2, and the reset control MOS transistor Q3 are shared between the pixel structures PIXEL1 and PIXEL2, which reduces the area of a semiconductor chip of the semiconductor integrated circuit 1. As a result, a low cost back-side illuminated CMOS image sensor can be provided. In comparison with the related art CMOS image sensor with the same size of pixels, the more area for the photodiode (PD) can be ensured, which can improve the sensitivity and number of saturated electrons (the amount of stored electrons).

### <<Layout of Transistors Shared Between Pixel Structures>>

FIG. 10 shows the layout structure of a semiconductor chip of the semiconductor integrated circuit 1 in which the readout MOS transistor Q1, the vertical selection MOS transistor Q2, and the reset control MOS transistor Q3 are shared between the pixel structures PIXEL1 and PIXEL2 in the back-side illuminated CMOS image sensor of the fourth embodiment of the invention shown in FIG. 9.

At the lower left of FIG. 10, the two pixel structures PIXEL1 and PIXEL2 shown in FIG. 9, the reset control MOS transistor Q3, the readout MOS transistor Q1, and the vertical selection MOS transistor Q2 are arranged. On the left side at the lower left of FIG. 10, first, the second transfer gate 2TR having the gate electrode G3 of the first pixel structure PIXEL1, the charge storing portion TH including the gate electrode G2, and the capacitance FD_C of the PN junction formed by the N⁺impurity region 4 of the floating diffusion (FD) are arranged to form the photodiode (PD) directly under the charge storing portion TH. Next, the reset control MOS transistor Q3 serving as a shared circuit element and a ground wiring P-WellGND for coupling the P-type well region P-Well of the semiconductor integrated circuit 1 to the ground potential GND are formed on the right side of the capacitance FD_C, the second transfer gate 2TR, and the charge storing portion TH of the first pixel structure PIXEL1. The ground wiring P-WellGND is brought into ohmic contact with the P⁺impurity region 5. Further, the capacitance FD_C of the second pixel structure PIXEL1, the second transfer gate 2TR including the gate electrode G3, and the charge storing portion TH including the gate electrode G2 are arranged on the right side of the capacitance FD_C of the reset control transistor Q3 and the ground wiring P-WellGND to thereby form the photodiode (PD) directly under the charge storing portion TH. Finally, the readout MOS transistor Q1 and the vertical selection MOS transistor Q2 are arranged as a shared circuit element on the right side of the capacitance FD_C, the second transfer gate 2TR, and the charge storing portion TH of the second pixel structure PIXEL2. Likewise, the same arrangement of elements is also performed at the upper left, lower right, and upper right of FIG. 10.

### Fifth Embodiment

<<CMOS Image Sensor with Horizontal and Vertical Scanning Circuits>>

FIG. 11 shows the structure of a back-side illuminated CMOS image sensor according to the most specific fifth embodiment of the invention.

That is, the back-side illuminated CMOS image sensor of the most specific fifth embodiment of the invention shown in FIG. 11 includes a plurality of rows ROW_1, ROW_2, and ROW_3 to ROW_N, and a plurality of columns CL_1, CL_2, and CL_3 to CL_M of a photodiode array (PDA). At points of intersection between the rows and columns, the pixel structures P11, P12 to P1M, P21, P22 to P2M to PN1, and PN2 to PNM are respectively located and integrated in the semiconductor chip of the semiconductor integrated circuit 1.

Theses pixel structures P11, P12 to P1M, P21, P22 to P2M to PN1, and PN2 to PNM can use anyone of the back-side illuminated CMOS image sensor of the first embodiment shown in FIGS. 1 and 2, the back-side illuminated CMOS image sensor of the second embodiment shown in FIG. 3, and the back-side illuminated CMOS image sensors of the third embodiment shown in FIGS. 7 and 8.

A vertical scanning circuit 10 and a horizontal scanning circuit 11 are coupled to the photodiode array (PDA). An output circuit 12 is coupled to the horizontal scanning circuit 11. The vertical scanning circuit 10, the horizontal scanning circuit 11, and the output circuit 12 each are comprised of the CMOS circuit.

The vertical scanning circuit 10 supplies a first selection control signal SEL_1 and a second transfer gate driving signal SG3_1 to the gate of the vertical selection transistor Q2, and the gate electrode G3 of the second transfer gate 2TR in each of the pixel structures P11, and P12 to P1M of the first row ROW_1, respectively. The vertical scanning circuit 10 respectively supplies a second selection control signal SEL_2 and a second transfer gate driving signal SG3_2 to the gate of the vertical selection transistor Q2 and the gate electrode G3 of the second transfer gate 2TR in each of the pixel structures P21, and P22 to P2M of the second row ROW_2, respectively. Likewise, the vertical scanning circuit 10 supplies an N-th selection control signal SEL_N and a second transfer gate driving signal SG3_N to the gate of the vertical selection transistor Q2 and the gate electrode G3 of the second transfer gate 2TR in each of the pixel structures PN1, and PN2 to PNM of the Nth row ROW_1, respectively.

Like the pixel structures P11, and P21 to PN1 of the first column CL_1, and the pixel structures P12, and P22 to PN2 of the second column CL_2, a gate driving signal SG4 is supplied to the gate electrode G4 of the overflow control MOS transistor Q4 in each of the pixel structures P1M, and P2M to PNM of the M-th column CL_M. Likewise, a gate driving signal SG2 is supplied to the gate electrode G2 of the charge storing portion TH. A reset control signal RESET is supplied to the gate electrode of the reset control MOS transistor Q3.

A first vertical signal line VSL1 is commonly coupled to the sources of the vertical selection transistors Q2 of the pixel structures P11, and P21 to PN1 in the first column CL_1. A second vertical signal line VSL2 is commonly coupled to the sources of the vertical selection transistors Q2 of the pixel structures P12, and P22 to PN2 in the second column CL_2. Likewise, the M-th vertical signal line VSLM is commonly coupled to the sources of the vertical selection transistors Q2 of the pixel structures P1M, and P2M to PNM in the M-th column CL_M. The first vertical signal line VSL1, the second vertical signal line VSL2, and the M-th vertical signal line VSLM are respectively coupled to an input terminal of the output circuit 12 via the horizontal scanning circuit 11.

FIG. 12 is a diagram showing signal waveforms relating to the operation of the back-side illuminated CMOS image sensor in the fifth embodiment of the invention shown in FIG. 11.

As shown in FIG. 12, at the time TO, the operation of the back-side illuminated CMOS image sensor according to the fifth embodiment of the invention shown in FIG. 11 is started.

At the time T1, the reset control signal RESET supplied to the gate electrode of the reset control MOS transistor Q3 of each of pixel structures contained in the photodiode array (PDA) is changed from a low level to a high level. The gate driving signal SG2_1 supplied to the gate electrode G2 of the charge storing portion TH of each of the pixel structures P11, and P12 to P1M in the first row Row_1 is changed from a low level to a high level. The gate driving signal SG2_2 supplied to the gate electrode G2 of the charge storing portion TH of the pixel structures P21, and P22 to P2M in the second row Row_2 is changed from a low level to a high level. And the gate driving signal (not shown) supplied to the gate electrode G2 of the charge storing portion TH of each of the pixel structures in the remaining rows is changed from a low level to a high level. Thereafter, the gate driving signal SG3_1 supplied to the gate electrode G3 of the second transfer gate 2TR of each of the pixel structures P11, and P12 to P1M in the first row Row _1 is changed from a low level to a high level. And, the gate driving signal SG3_2 supplied to the gate electrode G3 of the second transfer portion 2TR of each of the pixel structures P21, and P22 to P2M in the second row Row_2 is changed from a low level to a high level. And the gate driving signal (not shown) supplied to the gate electrode G3 of the second transfer portion 2TR of each of the pixel structures in all the remaining rows is changed from a low level to a high level.

At the time T2, the gate driving signal SG2_1 and the gate driving signal SG2_2 are changed from the high level to the low level. At the time T3, the gate driving signal SG3_1 and the gate driving signal SG3_2 are changed from the high level to the low level. Thus, during the period from the time T1 to the time T3, the N⁺impurity region 4 and the charge storing portion TH of the floating diffusion (FD) and the photodiode (PD) in all pixel structures contained in the photodiode array (PDA) are reset to the initial state.

At the time T4, the gate driving signal SG2_1 and the gate driving signal SG2_2 are changed from the low level to the high level. During the period from the time T3 to the time T4, all pixel structures contained in the photodiode array (PDA) are simultaneously exposed, so that signal electrons are stored in the N⁻impurity region 2 of the photodiode (PD) of each of the pixel structure.

Since at the time T5 the gate driving signal SG2_1 and the gate driving signal SG2_2 are changed from the high level to the lower level, during the period from the time T4 to the time T5, the signal electrons are transferred from the N⁻impurity region 2 of the photodiode (PD) to the charge storing portion TH in all pixel structures contained in the photodiode array (PDA).

The gate driving signal SG4 supplied to the gate electrode G4 of the overflow control MOS transistor Q4 is changed from a low level to a high level at the time slightly delayed from the time T5. On the other hand, at a slightly early time before the time T6, the reset control signal RESET supplied to the gate electrode of the reset control MOS transistor Q3 is changed from the high level to the lower level. Thus, during the period substantially from the time T5 to the time T6, the reset operation of the photodiode (PD) is carried out by the conduction of the overflow control MOS transistor Q4, and the reset operation of the N⁺impurity region 4 of the floating diffusion (FD) is carried out by the conduction of the reset control MOS transistor Q3.

At the time T6, the first selection control signal SEL_1 supplied to the gate of the vertical selection transistor Q2 with respective pixel structures P11, and P12 to P1M in the first row Row_1 is changed from a low level to a high level. Further, at the time T7, the first selection control signal SEL_1 is changed from the high level to the low level. Thus, during the period substantially from the time T6 to the time T7, dark readout of the pixel structures P11 and P12 to P1M in the first row ROW _1 is performed. The term “dark readout” as used herein means readout of a voltage level from the N⁺impurity region 4 of the floating diffusion (FD) directly after the reset operation.

The second transfer gate driving signal SG3_1 supplied to the gate electrode G3 of the pixel structures P11 and P12 to P1M in the first row Row_1 is changed from the low level to the high level at the time slightly delayed from the time T7. On the other hand, at an early time before the time T8, the second transfer gate driving signal SG3_1 is changed from the high level to the low level. Thus, during the period substantially from the time T7 to the time T8, the signal electrons stored in the charge storing portion TH in each of pixel structures P11 and P12 to P1M in the first row Row_1 are transferred to the N⁺impurity region 4 of the floating diffusion (FD).

At the time T8, the first selection control signal SEL_1 supplied to the gate of the vertical selection transistor Q2 of each of the pixel structures P11 and P12 to P1M in the first row Row_1 is changed from the low level to the high level. Further, at the time T9, the first selection control signal SEL_1 is changed from the high level to the low level. Thus, during the period substantially from the time T8 to the time T9, the signal electrons of the pixel structures P11 and P12 to P1M in the first row Row _1 are converted into a voltage in the N⁺impurity region 4 of the floating diffusion (FD), and read out into the first vertical signal line VSL1, the second vertical signal VSL2 to the M-th vertical signal line VSLM.

The reset control signal RESET is changed from the low level to the high level at the time slightly delayed from the time T9. The reset control signal RESET is changed from the high level to the low level at a slightly early time before the time T10. Thus, during the period substantially from the time T9 to the time T10, the signal voltage of the N⁺impurity region 4 of the floating diffusion (FD) of each of the pixel structures is reset to the high-potential power supply voltage Vcc.

At the time T10, the second selection signal SEL_2 supplied to the gate of the vertical selection transistor Q2 of each of the pixel structures P21 and P22 to P2M in the second row Row_2 is changed from a low level to a high level. At the time T11, the second selection control signal SEL_2 is changed from the high level to the low level. Thus, during the period substantially from the time T10 to the time T11, the dark readout of the pixel structures P21 and P22 to P2M in the second row ROW_2 is performed. As described above, the term “dark readout” means the readout of a voltage level from the N⁺impurity region 4 of the floating diffusion (FD) directly after the reset operation.

The second transfer gate driving signal SG3_2 supplied to the gate electrode G3 of the second transfer gate 2TR of each of the pixel structures P21 and P22 to P2M in the second row Row_2 is changed from the low level to the high level at the time slightly delayed from the time T11. The second transfer gate driving signal SG3_2 is changed from the high level to the low level at the slightly early time before the time T12. Thus, during the period substantially from the time T11 to the time T12, the signal electrons stored in the charge storing portion TH are transferred to the N⁺impurity region 4 of the floating diffusion (FD) in each of the pixel structures P21 and P22 to P2M in the second row Row_2.

At the time T12, the second selection control signal SEL_2 supplied to the gate of the vertical selection transistor Q2 of each of the pixel structures P21 and P22 to P2M in the second row Row_2 is changed from the low level to the high level. At the time T13, the second selection control signal SEL_2 is changed from the high level to the low level. Thus, during the period substantially from the time T12 to the time T13, the signal electrons of the pixel structures P21 and P22 to P2M in the second row Row_2 are converted into respective voltages in the N⁺impurity region 4 of the floating diffusion (FD), which are respectively read out in the first vertical signal line VSL1, and the second vertical signal line VSL2 to the M-th Vertical signal line VSLM.

After the time T14, the same readout operation is performed on the pixel structures in all the remaining rows, so that imaging information is read out from the CMOS output circuit 12 by simultaneous exposure, that is, global shutter imaging from all pixel structures contained in the photodiode array (PDA) during the imaging period from the time T3 to the time T4.

The invention made by the inventors have been specifically described based on various embodiments, and thus is not limited thereto. It is apparent that various variations can be made to the disclosed embodiments without departing from the scope of the invention.

For example, in the back-side illuminated CMOS image sensor or the like according to the first embodiment of the invention shown in FIG. 1, the order of coupling the readout MOS transistor Q1 and the vertical selection MOS transistor Q2 in series can be changed. That is, the drain and source of the vertical selection MOS transistor Q2 are respectively coupled to the high-potential power source voltage Vcc and the drain of the readout MOS transistor Q1, and the source of the readout MOS transistor Q1 is directly coupled to the vertical signal line VSL.

In the back-side illuminated CMOS image sensor or the like of the first embodiment of the invention shown in FIG. 1, the first transfer gate 1TR can be changed from the PN junction structure to the surface-type MOS capacitor structure including the gate electrode, like the second transfer gate 2TR. At that time, it is necessary to protrude a part of the N⁻impurity region 2 of the photodiode (PD) until the part comes close to the surface of the silicon semiconductor directly under the gate electrode of the first transfer gate 1TR.

The gate electrode G4 of the overflow control MOS transistor Q4 and the N+impurity region 6 of the N-type overflow drain (OFD) shown in FIGS. 1 and 3 can be formed over the surface of the silicon semiconductor in the same manner as that shown in FIG. 7. In such a case, only the opening OP formed in the light shielding film SHL may be disposed at the back surface of the silicon semiconductor substrate 1. Since the area of the opening OP and the photodiode (PD) 3 with respect to the incident light LG is increased, the sensitivity of the photodiode (PD) 3 with respect to the incident light LG can be improved.

It is apparent that a CMOS image sensor enabling color photography can be provided by applying a microlens and color filters of red, green, and blue as three primary colors of light to the pixel structures in the back-side illuminated CMOS image sensor according to the most specific fifth embodiment of the invention shown in FIG. 11.

What is claimed is:

1. A back-side illuminated solid-state imaging device, comprising:
a semiconductor substrate;
a MOS transistor formed over a front surface of the semiconductor substrate;
a photodiode formed at the semiconductor substrate and adapted to respond to an incident light applied to a back surface opposite to the front surface of the semiconductor substrate; and
a charge storing portion formed over the front surface of the semiconductor substrate located above a main part of the photodiode so as to achieve a global shutter function.

2. The back-side illuminated solid-state imaging device according to claim 1,
wherein the photodiode is comprised of a P-type impurity region and an N-type impurity region formed in the semiconductor substrate, and
wherein the main part of the photodiode is comprised of the N-type impurity region.

3. The back-side illuminated solid-state imaging device according to claim 2, further comprising an N-type impurity semiconductor region for readout for forming a PN junction with the P-type impurity region formed at the semiconductor substrate, and
wherein stored charges read from the charge storing portion are converted into a signal voltage by a capacitance of the PN junction of the N-type impurity semiconductor region for readout, so that the signal voltage is supplied to a gate terminal of a readout MOS transistor among the MOS transistors.

4. The back-side illuminated solid-state imaging device according to claim 3,
wherein the N-type impurity region of the photodiode has a function of storing therein signal electrons in response to the incident light,
wherein said back-side illuminated solid-state imaging device further comprises, at the semiconductor substrate, a first transfer gate coupled between the N-type impurity region of the photodiode and the charge storing portion, and a second transfer gate coupled between the charge storing portion and the N-type impurity semiconductor region for readout,
wherein the first transfer gate has a function of transferring the signal electrons stored in the N-type impurity region of the photodiode to the charge storing portion, and
wherein the second transfer gate has a function of transferring the signal electrons stored in the charge storing portion to the N-type impurity semiconductor region for readout.

5. The back-side illuminated solid-state imaging device according to claim 4, wherein each of the charge storing portion and the second transfer gate includes a surface-type MOS capacitor including the P-type impurity region, a surface insulating film formed over the front surface of the semiconductor substrate, and a gate electrode.

6. The back-side illuminated solid-state imaging device according to claim 5, wherein the first transfer gate is formed by another PN junction between the N-type impurity region and the P-type impurity region located directly under the gate electrode of the charge storing portion.

7. The back-side illuminated solid-state imaging device according to claim 5, wherein an N-type impurity semiconductor region for storing therein the signal electrons is formed over the front surface of the semiconductor substrate directly under the gate electrode of the charge storing portion.

8. The back-side illuminated solid-state imaging device according to claim 5, wherein the N-type impurity semiconductor region for readout is set to a predetermined operation potential by a reset control MOS transistor among the MOS transistors.

9. The back-side illuminated solid-state imaging device according to claim 5,
wherein a drain-source current route of a vertical selection MOS transistor having a gate terminal to which a selection control signal is supplied among the MOS transistors is coupled in series to a drain-source current route of the readout MOS transistor, and
wherein the serial coupling between the readout MOS transistor and the vertical selection MOS transistor is established between the predetermined operation potential and a vertical signal line.

10. The back-side illuminated solid-state imaging device according to claim 5,
wherein a part of the N-type impurity region is formed to extend inside the semiconductor substrate directly under the N-type impurity semiconductor region for readout, and
wherein a P-type semiconductor region having a high concentration of impurities is formed between the N-type impurity semiconductor region for readout and the part of the N-type impurity region formed to extend inside the semiconductor substrate.

11. The back-side illuminated solid-state imaging device according to claim 5, wherein a light shielding film is formed over the back surface of the semiconductor substrate, and has an opening for introducing the incident light to be incident on the back surface of the semiconductor substrate, into the N-type impurity region of the photodiode.

12. The back-side illuminated solid-state imaging device according to claim 5,
wherein a plurality of pixel structures each having the photodiode, the first transfer gate, the charge storing portion, and the second transfer gate are formed at the semiconductor substrate, and
wherein the readout MOS transistor, the vertical selection MOS transistor, and the reset control MOS transistor are shared between the pixel structures.

13. The back-side illuminated solid-state imaging device according to claim 5,
wherein each of pixel structures located at points of intersection between a plurality of rows and a plurality of columns in an array includes the photodiode, the first transfer gate, the charge storing portion, the second transfer gate, the readout MOS transistor, the vertical selection MOS transistor, and the reset control MOS transistor, and
wherein the array is coupled to a vertical scanning circuit of a CMOS circuit and a horizontal scanning circuit of a CMOS circuit.

14. The back-side illuminated solid-state imaging device according to claim 13, wherein an output from the horizontal scanning circuit is coupled to an input of an output circuit of the CMOS circuit.
